(19) United States
(12) Patent Application Publication
(10) Pub. No.: US 2003/0168969 A1
(43) Pub. Date: Sep. 11, 2003

(54) Display panel substrate and display device

(76) Inventor: Takahisa Tanabe, Tsurugashima-shi (JP)

Correspondence Address: PERMAN & GREEN, 425 POST ROAD, FAIRFIELD, CT, 06824, US

(21) Appl. No.: 10/377,986

(22) Filed: Mar. 3, 2003

(30) Foreign Application Priority Data
Mar. 5, 2002 (JP) JP 2002-058538

(51) Int. Cl. H05B 33/00; H05B 33/08

(52) U.S. Cl. 313/500; 313/495

(57) ABSTRACT

A display device includes a wiring substrate and a pixel drive circuit board. The wiring substrate has two main surfaces. A plurality of display elements are formed on one main surface of the substrate. The substrate has a plurality of through holes filled with conductors such that the through holes correspond to the display elements, respectively. A plurality of electrical connections are formed on the other main surface of the substrate. Each display element is connected to the corresponding electrical connection via the corresponding through hole. The pixel drive circuit board has one or more drive ICs including a plurality of driver circuits. Each driver circuit has a terminal for connection to the corresponding electrical connection on the main surface of the substrate. This display device is easy to manufacture and has a high yield.

### BACKGROUND OF THE INVENTION

1. Field of the Invention

The present invention relates to a display device which includes a panel substrate such as a flat panel display device.

2. Description of the Related Art

Transparent liquid crystal display (referred to as “LCD”) devices are known as flat panel display devices in the art. In recent years, self luminescence emission type display panels (e.g., organic electroluminescent (EL) display devices) have become popular as another type of flat panel display device. The organic EL display device emits light, using an organic compound which becomes luminous (electroluminescent) upon application of a current.

A certain type of conventional organic EL display device is operated by an active matrix driving (addressing) scheme. A certain type of conventional LCD device is also controlled by the active matrix driving scheme. In general, the display device is fabricated in the following manner if the display device is driven by the active matrix scheme. A plurality of groups of thin film transistors (TFTs) are first arranged on a glass substrate in an array fashion, thereby preparing a so-called TFT substrate. The TFT is made from, for example, a semiconductor material such as silicon. Each TFT group includes several TFTs, and serves as a drive circuit for one pixel. A plurality of display elements (e.g., organic EL elements or liquid crystal elements) are then formed on the TFT substrate. The display device driven by the TFTs includes the drive circuits arranged in a matrix form. The drive circuits for respective pixels are arranged on the substrate in up and down (vertical) directions as well as right and left (horizontal) directions. Signal lines also extend in a matrix fashion on the substrate. By operating the drive circuits for the respective pixels using the signal lines, the display device creates an image on its screen.

Each TFT should be fabricated by a very high-precision process. A plurality of TFTs are formed on the substrate of the display device. In principle, the TFTs should be fabricated without defects. The screen of the display device is relatively large, and the TFTs are placed over the entire screen. Under these circumstances, an extremely sophisticated process is required to manufacture the TFT substrate, and the display device including the TFT substrate. This results in a high manufacturing cost. In particular, as the screen size becomes larger, it becomes very difficult to prepare a substrate without defects. Therefore, the yield (percentage of satisfactory products) drops and the display manufacturing cost dramatically increases.

One approach to solve this problem is disclosed in Japanese Patent Kokai No. 2001-92381 and will be briefly described here with reference to FIG. 1 of the accompanying drawings. In FIG. 1, the TFTs are not used in an organic EL display device, i.e., the TFT substrate is not used. Instead, drive ICs 3 are used. A plurality of organic EL elements 2 are formed on a multi-layer substrate 1, and the drive ICs 3 are directly mounted on the substrate 1 to drive the organic EL elements 2. Relatively complicated wiring is embedded in the substrate 1.

The multi-layer substrate including the embedded wiring barely has sufficient moisture resistance (humidity resistance) which is required by the organic EL. In addition, the multi-layer substrate including the embedded wiring is easy to deform upon heating so that the substrate shrinks and/or bends (warps) during a manufacturing process. Further, adequate flatness of the substrate is difficult to achieve so that the organic EL film formed on the substrate cannot function in a desired performance.

### SUMMARY OF THE INVENTION

An object of the present invention is to provide a display device that is easy to manufacture and has a high yield.

According to one aspect of the present invention, there is provided a substrate arrangement for a display panel, comprising: a substrate having first and second main surfaces; a plurality of electrodes formed on the first main surface of the substrate; a plurality of through holes formed in the substrate and filled with conductors such that the conductors are connected to the electrodes, respectively; and a plurality of electrical connections coupled to the second main surface of the substrate such that the electrical connections are connected to the conductors, respectively. The electrodes may be arranged in a matrix fashion. The substrate may have a single layer structure. The substrate may be made from glass, plastic or ceramics to impart rigidity, waterproof property and/or deformation resistance against heat, to the substrate.

According to a second aspect of the present invention, there is provided a display device comprising: a wiring substrate having first and second main surfaces; a plurality of display elements provided on the first main surface of the wiring substrate; a plurality of through holes formed in the wiring substrate and filled with conductors such that the conductors are connected to the display elements, respectively; a plurality of electrical connections coupled to the second main surface of the wiring substrate such that the electrical connections are connected to the conductors, respectively; and a pixel drive circuit board including a plurality of drive ICs and a plurality of terminals such that the drive ICs are connected to the electrical connections via the terminals respectively. The electrical connections may be conductive pads, and the conductive pads may be coupled with the terminals via a plurality of conductive bumps, respectively. The display elements may be arranged in a matrix fashion. The pixel drive circuit board may include a plurality of transistors to drive pixels. The wiring substrate may have a single layer structure. Each through hole may be a short straight hole. The wiring substrate may be made from glass, plastic or ceramics to impart rigidity, waterproof property and/or deformation resistance against heat, to the wiring substrate.

The TFT substrate for the active matrix drive scheme is replaced with the wiring substrate, and the active circuits (driver circuits or drive ICs) are provided on the separate board (pixel drive circuit board). Therefore, manufacturing of the wiring board which supports the display elements becomes extremely easy. This contributes to a manufacturing cost reduction of the display device. In particular, the problem of the TFT substrate is eliminated. Specifically, even if the substrate size increases, the substrate of the invention has adequate flatness and it is possible to manufacture the substrates at a high yield. As mentioned before, the TFT substrate suffers from flatness irregularity and a low yield when the substrate size increases. According to the present invention, therefore, the cost reduction effect becomes more significant as the display device size increases.

Since the substrate has a single layer structure, the substrate has adequate flatness so that the substrate and the display device do not create problems related to the non-flatness.

Since pixel driver circuits are integrated in the drive ICs, individual transistors are significantly superior to the TFT in terms of performance, reliability and quality. The display device of the invention can be operated by a high precision drive scheme so that various circuit technologies can be applied. This contributes to displayed image quality improvement, power consumption reduction and reliability improvement.

Since the drive ICs and other electronic parts can be easily attached to the pixel drive circuit board, additional functions and capabilities can be given to the display device.

### BRIEF DESCRIPTION OF THE DRAWINGS

FIG. 1 schematically illustrates a cross sectional view of an organic EL display device including a multi-layer substrate;

FIG. 2 schematically illustrates a cross sectional view of an organic EL display device according to an embodiment of the present invention;

FIG. 3 illustrates a block diagram of the organic EL display device shown in FIG. 2; and

FIG. 4 illustrates a display device having a quartered screen together with four drive circuit boards.

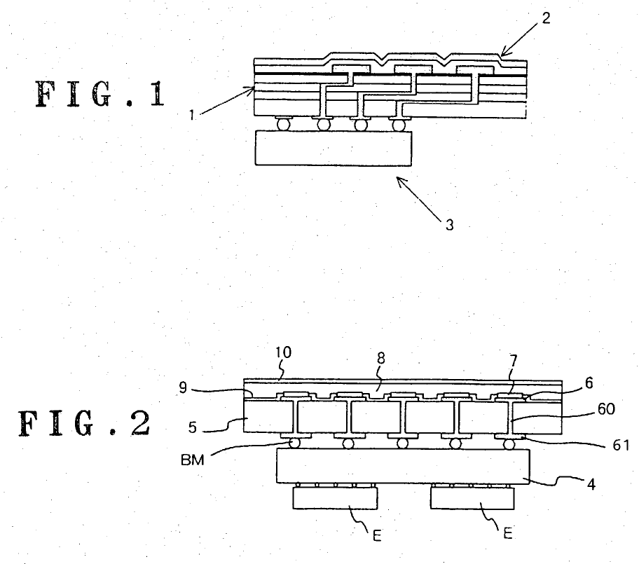

### DETAILED DESCRIPTION OF THE INVENTION

Embodiments of the present invention will be described with reference to the accompanying drawings.

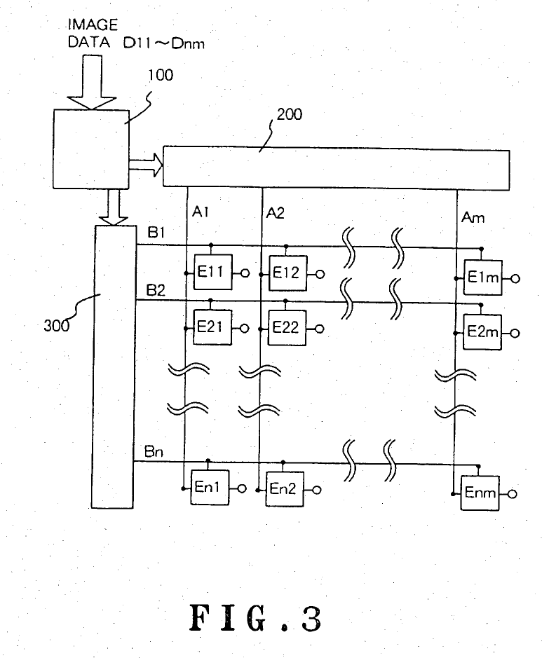

Referring to FIG. 2, a cross sectional view of an organic EL display device is schematically illustrated. A plurality of EL elements are arranged on a substrate 5 in a matrix fashion. In this embodiment, the substrate 5 is a double-sided board. The term “double-sided”, as used herein, means that both surfaces of the substrate are main (major, principal) surfaces. A plurality of through holes 60 are formed in the substrate 5. Each through hole 60 is a short and straight hole. Each through hole 60 is plated with an electrically conductive material. The through holes 60 are common through holes which are generally used in a printed circuit board. In the illustrated embodiment, each through hole 60 is filled with a conductive material or conductor such as aluminum. The term “through hole” sometimes means the combination of the hole itself and the filled material. A pixel drive circuit board 4 is attached to the substrate 5. The substrate 5 serves as a wiring board. A plurality of display elements (organic EL elements) are formed on one of the main surfaces of the substrate 5. The substrate 5 is insulative and made from glass or plastic. Pixels of the organic EL display device are formed from the organic EL elements. The organic EL element has a multi-layer structure defined by the substrate 5, a cathode 6 formed on the substrate 5, the organic EL material layer 7 formed on the cathode 6, and an anode 8 formed on the organic EL material layer 7. The cathode 6 is a metal electrode. The organic EL material layer 7 includes a light emissive layer. The anode 8 is a transparent electrode made from ITO (Indium Tin Oxide). The cathode 6 is covered with an insulative layer 9. The insulative layer 9 also extends between the anode 8 and cathode 6. The upper surface of the anode 8 is entirely covered with a protection layer or film 10. The protection layer 10 is transparent. It should be noted that the organic EL layer 7 may include a hole injection layer, a hole transporting layer and/or an electron transporting layer. It is assumed in the illustrated embodiment that the substrate 5 and the pixel drive circuit board 4 are not light-transmissive. Therefore, the light emitted from the organic EL material layer 7 is directed upwards from the top of the substrate 5. This structure is called a “top emission type” structure.

Although the cathode 6 is located on the substrate 5 in this embodiment, the anode 8 may be the metal electrode and located on the substrate 5, and the cathode 6 may be a transparent electrode and located over the anode 8. It should also be noted that the transparent electrode may be made from a material other than ITO, such as IZO (Indium Zinc Oxide). Moisture penetration to the organic EL elements is prevented by the insulative layer 9 in the illustrated embodiment. It should be noted that the moisture penetration can also be prevented if the substrate 5 itself is made from a waterproof material.

The substrate 5 has the through holes 60 and a plurality of conductive pads 61. Each through hole 60 is associated with one conductive pad 61. The conductive pads 61 are formed on the other main surface (lower surface) of the substrate 5. Each conductive pad 61 is connected to the cathode 6 of the corresponding organic EL element formed on the upper surface of the substrate 5 via the corresponding conductor-filled through hole 60. When viewed from the pixel drive circuit board 4, it can be said that the organic EL elements are formed on the opposite side of the substrate 5. This side of the substrate 5 is referred to as “pixel surface”. On the pixel surface of the substrate 5, electrodes are patterned (printed) for the pixels. The pixel electrodes are connected to the pads 61 on the pixel surface of the substrate 5 by viaholes and printed pattern.

A plurality of drive ICs (integrated circuits) E are mounted on the pixel drive circuit board 4 to drive the display elements. The pixel drive circuit board 4 also has a plurality of terminals BM to connect the drive ICs “E” to the pads 61 of the substrate 5. By attaching the pixel drive circuit board 4 to the substrate 5, the display device is fabricated. The drive ICs “E” are provided on one surface of the drive circuit board 4, and the terminals BM are provided on the opposite surface of the drive circuit board 4.

In order to couple the pixel drive circuit board 4 with the substrate 5, conductive bumps are formed on electrodes of either the circuit board 4 or the substrate 5. In this embodiment, the bumps are the terminals BM formed on the electrodes of the pixel drive circuit board 4. The bumps have a low melting point. The bumps are made from a tin alloy, not including lead, by plating, vapor deposition, dip soldering or the like. When mounting the pixel drive circuit board 4 on the substrate 5, the pixel drive circuit board 4 is held below the substrate 5 and aligned with the substrate 5. Then, the substrate 5 is positioned on the pixel drive circuit board 4, heated to about 180° C. to about 220° C. and pressed against each other, thereby connecting the substrate 5 with the pixel drive circuit board 4. In this manner, the connection between the pixel drive circuit board 4 and the substrate 5 is established by the pads 61 and bumps BM only. Since the pixel drive circuit board 4 has to have a number of terminals, the pixel drive circuit board 4 preferably has BGA (Ball Grid Array) terminals as output terminals. Alternatively, the pixel drive circuit board 4 may have PGA (Pin Grid Array) terminals as the output terminals.

The wiring between the drive ICs “E” themselves on the pixel drive circuit board 4 and the wiring between the drive ICs “E” and external parts are patterned (printed) on the lower surface of the pixel drive circuit board 4. In the illustrated embodiment, a terminal pitch (pitch between the terminals BM) of the pixel drive circuit board 4 is equal to a pixel pitch of the substrate 5.

The drive ICs “E” on the pixel drive circuit board 4 contain a plurality of pixel driver circuits to drive a plurality of pixels respectively. One or more drive ICs “E” are used to drive all the pixels of the display device. The pixel drive circuit board 4 has a printed wiring pattern necessary for the matrix drive.

An arbitrary IC package, such as DIP (dual in-line package), ZIP (zigzag in-line package), SIP (single in-line package) or PGA (pin grid array), may be mounted on the pixel drive circuit board 4. The drive ICs “E” may include not only the pixel driver circuits but also various peripheral circuits to, for example, transfer brightness data and timing signals. Further, the pixel drive circuit board 4 may mount on itself other integrated circuits and/or electronic parts, which are not directly related to the pixel drive.

Referring to FIG. 3, the drive IC assembly (the combination of the drive ICs “E” on the circuit board 4) is schematically illustrated. The drive IC assembly includes a light emission control circuit 100, a data drive circuit 200, a scanning circuit 300 and pixel driver circuits E11 to Enm. Row lines (horizontal lines) B1 to Bn extend from the scanning circuit 300, and column lines (vertical lines) A1 to Am extend from the data drive circuit 200 perpendicularly to the row lines. The pixel driver circuits E11 to Enm are provided at the crossings of the row lines B1 to Bn and the column lines A1 to Am respectively. Each of the pixel driver circuits E11 to Enm is associated with one pixel.

The light emission control circuit 100 receives image data D11 to Dnm of one screen's worth or one block's (n rows, m columns) worth. The light emission control circuit 100 converts the input image data D11 to Dnm into pixel data which fit the pixel driver circuits E11 to Enm, and sequentially supplies the pixel data to the data drive circuit 200. The pixel data are supplied for one display line at a time. For example, the pixel data D11 to D1m are first supplied to the data drive circuit 200, and transferred to the pixel driver circuits E11 to E1m. The pixel data D11 to D1m are m-bit data to specify light emission brightness (gradation level or tone) of the first display line. The driver circuits E11 to Elm cause the first display line to be luminous. The bit number of the pixel data is determined by the number of the gradation levels of the display device.

The light emission control circuit 100 supplies a scan line selection signal to the scanning circuit 300 in synchronization with feeding of pixel data of each display line, such that each display line is successively scanned.

When the drive IC assembly is driven based on the pixel data, the screen on the pixel drive circuit board 4 shows one field of image, i.e., one field of light emission pattern, derived from the input image data. If the number of the column lines A1 to Am and the number of the row lines B1 to Bn increase, the size of the data drive circuit 200 and the scanning circuit 300 correspondingly increase.

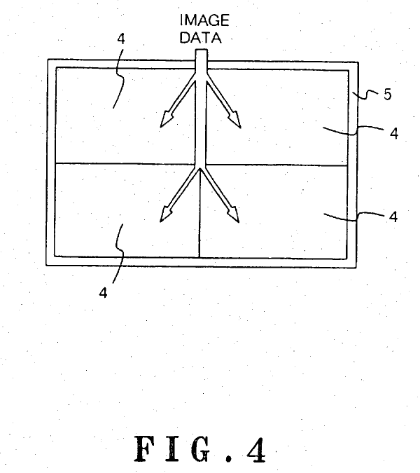

Referring to FIG. 4, another example of the display device is schematically illustrated. The screen of the display device is divided into four segments (four-panel structure), and four pixel drive circuit boards 4 are attached to the back side of the single substrate 5.

As understood from the foregoing, the TFTs are not used in the display device in the embodiments of the invention; instead, the pixel drive circuit board 4 having the drive ICs is used. The separate substrate 5 is attached to the separate pixel drive circuit board 4 to form the display device in the embodiments of the invention.

Although the substrate 5 is coupled with the pixel drive circuit board 4 by the bumps BM in the illustrated embodiments, the substrate 5 may directly be laminated over the pixel drive circuit board 4.

It should be noted that the present invention can be applied not only to the organic EL display device, but also other types of display device such as an LCD device, an FED (Field Emission Display) device and an inorganic EL display device.

The substrate 5 can be prepared by conventional printed board manufacturing technology. The drive ICs “E” on the circuit board 4 have a size which can be fabricated by a relatively old process. Therefore, no special facilities are required to manufacture the substrate 5, the circuit board 4 and the display device.

This application is based on a Japanese patent application No. 2002-58538, and the entire disclosure thereof is incorporated herein by reference.

What is claimed is:

1. A substrate arrangement for a display panel, comprising:
a substrate having first and second surfaces;
a plurality of electrodes formed on the first surface of the substrate;
a plurality of through holes formed in the substrate and filled with conductors such that the conductors are connected to the plurality of electrodes, respectively; and
a plurality of electrical connections coupled to the second surface of the substrate such that the plurality of electrical connections are connected to the conductors, respectively.

2. The substrate arrangement according to claim 1, wherein the plurality of electrodes are arranged in a matrix fashion.

3. The substrate arrangement according to claim 1, wherein each of the plurality of through holes is plated with an electrically conductive material.

4. The substrate arrangement according to claim 1, wherein the substrate has a single layer structure.

5. The substrate arrangement according to claim 1, wherein the plurality of electrodes are metal electrodes.

6. The substrate arrangement according to claim 1, wherein the substrate prohibits light transmission through the substrate.

7. The substrate arrangement according to claim 1, wherein the plurality of electrical connections are a plurality of conductive pads formed on the second surface of the substrate.

8. The substrate arrangement according to claim 1, wherein the plurality of electrical connections are a plurality of conductive pads formed on the second surface of the substrate and a plurality of conductive bumps respectively connected to the plurality of conductive pads.

9. The substrate arrangement according to claim 8, wherein the plurality of conductive bumps have a low melting point.

10. The display device according to claim 1, wherein the substrate is made from glass, plastic or ceramics.

11. A display device comprising:
a wiring substrate having first and second surfaces;
a plurality of display elements provided on the first surface of the wiring substrate;
a plurality of through holes formed in the wiring substrate and filled with conductors such that the conductors are connected to the plurality of display elements, respectively;
a plurality of electrical connections coupled to the second surface of the wiring substrate such that the plurality of electrical connections are connected to the conductors, respectively;
a pixel drive circuit board;
a plurality of driver circuits provided on the pixel drive circuit board; and
a plurality of terminals provided on the pixel drive circuit board such that the plurality of driver circuits are connected to the plurality of electrical connections via the plurality of terminals, respectively.

12. The display device according to claim 11, wherein the plurality of electrical connections are a plurality of conductive pads, and the plurality of conductive pads are coupled with the plurality of terminals via a plurality of conductive bumps.

13. The display device according to claim 11, wherein the plurality of display elements are arranged in a matrix fashion.

14. The display device according to claim 11, wherein each of the plurality of through holes is plated with an electrically conductive material.

15. The display device according to claim 11, wherein the wiring substrate has a single layer structure.

16. The display device according to claim 11, wherein the plurality of display elements are organic EL display elements.

17. The display device according to claim 11, wherein the wiring substrate prohibits light transmission through the wiring substrate.

18. The display device according to claim 11, wherein the pixel drive circuit board includes a plurality of board segments attached to the wiring substrate.

19. The display device according to claim 12, wherein the plurality of conductive bumps have a low melting point.

20. The display device according to claim 11, wherein the wiring substrate is made from glass, plastic or ceramics.
